(19) United States
(12) Patent Application Publication
(10) Pub. No.: US 2014/0057420 A1
(43) Pub. Date: Feb. 27, 2014

(54) PROCESS FOR PRODUCING A POLYCRYSTALLINE LAYER

(71) Applicants: Martin Stutzmann, Erding (DE); Tobias Antesberger, Schernfeld (DE)

(72) Inventors: Martin Stutzmann, Erding (DE); Tobias Antesberger, Schernfeld (DE)

(73) Assignee: Dritte Patentportfolio Beteiligungsgesellschaft mbH & Co. KG, Schoenefeld/Waltersdorf (DE)

(21) Appl. No.: 14/113,008

(22) PCT Filed: Mar. 16, 2012
(86) PCT No.: PCT/EP12/54623

§ 371 Date: Oct. 21, 2013

(30) Foreign Application Priority Data
Apr. 21, 2011 (DE) 10 2011 002 236.8

(51) Int. Cl. H01L 21/02

(52) U.S. Cl. CPC H01L 21/02595; H01L 21/0262; H01L 21/02672
USPC 438/487

(57) ABSTRACT

A process is provided for producing a polycrystalline layer. This process includes the steps of: applying to a substrate a layer sequence comprising at least one amorphous starting layer provided with impurities, a metallic activator layer, and a cleaning layer based on titanium or titanium oxide arranged between the starting layer and the activator layer for withdrawing the impurities from the starting layer; and carrying out a heat treatment after the layer sequence has been applied for forming a polycrystalline end layer.

### CROSS-REFERENCE TO RELATED APPLICATIONS

This application is a Section 371 of International Application No. PCT/EP2012/054623, filed Mar. 16, 2012, which was published in the German language on Oct. 26, 2012, under International Publication No. WO 2012/143186 Al and the disclosure of which is incorporated herein by reference.

### BACKGROUND OF THE INVENTION

The present invention relates to a process for producing a polycrystalline layer applied on a substrate. Such processes are of great importance for electronics on large areas, e.g. for solar cells or flat screens.

The prior art discloses various production processes of this type, e.g. solid-phase crystallization or laser-induced crystallization. However, these processes either produce only very small crystallites or require high process temperatures. Therefore, the aluminum-induced layer exchange (ALILE) process was proposed as a promising alternative for obtaining coarse-grained high-quality polycrystalline films. In this case, an amorphous precursor material is crystallized at relatively low temperatures.

One process of this type is described, for example, in European patent application publication EP 2 133 907 A1, which proposes a process for producing polycrystalline layers, comprising the process steps of:
applying to a substrate a layer sequence, comprising at least an amorphous starting layer, a metallic activator layer, and an oxide layer arranged between the starting layer and the activator layer; and
carrying out a thermal treatment for forming a polycrystalline end layer; characterized in that the oxide layer is produced on the basis of an oxide of a transition metal with which an oxide layer can be produced that is stable during the thermal treatment.

With the use of silicon as an amorphous starting layer (precursor material), and aluminum as an activator layer, a polycrystalline silicon film is produced, which is saturated with aluminum and is thus highly p-type doped, with charge carrier densities of up to 10¹⁹ cm⁻³ or more. In this case, however, it is a result of the close contact between the aluminum and the amorphous silicon. Such high charge carrier densities are unsuitable for most applications and have to be adapted by post-processing treatments. In the related silver-induced layer exchange process (Ag-induced layer exchange, AgILE), silver is used instead of aluminum. In this case, the layers of silver/amorphous silicon are separated by a thin diffusion barrier and subjected to heat treatment at temperatures below the eutectic point for Ag—Si of 1109° K. The positions of the original silicon starting layer and of the silver activation layer are completely exchanged and a crystallization of the originally amorphous silicon is formed. With the use of perfectly pure silicon, the process would nominally lead to an undoped polycrystalline silicon layer. In practice, however, silicon used in semiconductor production often still has certain impurities.

Consequently, the density of impurity atoms and charge carriers may be higher than desired even in the AgILE process.

So-called “dirty silicon” having high levels of impurities is obtainable particularly cost- effectively. Here, however, it is disadvantageous that the density of the impurity atoms is far above the value required for many applications.

### BRIEF SUMMARY OF THE INVENTION

Accordingly, a problem addressed by the present invention is that of providing a process for producing a polycrystalline end layer in which the polycrystalline end layer has a lower density of impurities than the contaminated precursor material.

According to a first aspect of the invention, this problem is solved by a process for producing a polycrystalline layer in a cleaning manner, comprising the steps of:
applying to a substrate a layer sequence comprising at least
   an amorphous starting layer provided with impurities,
   a metallic activator layer, and
   a cleaning layer based on titanium or titanium oxide arranged between the starting layer and the activator layer and serving for withdrawing the impurities from the starting layer; and
carrying out a thermal treatment after applying the layer sequence for the purpose of forming a polycrystalline end layer.

In accordance with a further aspect of the invention, the problem is solved by a process for setting the doping in polycrystalline silicon, comprising the steps of:
applying to a substrate a layer sequence comprising at least
   an amorphous starting layer provided with impurities,
   a metallic activator layer, and
      a cleaning layer based on titanium or titanium oxide arranged between the starting layer and the activator layer; and
   carrying out a thermal treatment after applying the layer sequence for the purpose of forming a polycrystalline end layer;
wherein the doping can be set or is set by a suitable choice of the titanium layer thickness.

It goes without saying that the doping can also be supplementarily influenced in some other way as, for example, by corresponding pre-doping of the amorphous starting layer provided with impurities.

The novel process is based on the insight that a cleaning layer based on titanium or titanium oxide between the amorphous starting layer and the activator layer has the effect that impurities are withdrawn from the amorphous starting layer and, consequently, no longer contribute to an increased density of impurity atoms there.

It was possible to show in experiments that a concentration of 10¹⁹ cm⁻³ boron impurity atoms present in the starting layer without a titanium cleaning layer was able to be reduced to merely less than 10¹⁷ cm⁻³. A titanium cleaning layer having a thickness of 2 nm had been used for this purpose. The observed reduction in the boron concentration was clearly attributable experimentally to the withdrawal function of the titanium cleaning layer.

Further experiments have shown that different thicknesses of the titanium cleaning layer lead to different degrees of cleaning effect. Consequently, it is thus possible to set the density of the impurity atoms in the resulting polycrystalline end layer through the choice of the thickness of the titanium cleaning layer.

The problem stated above is thus completely solved.

In accordance with one possible embodiment of the invention, it is provided that the impurities are boron impurities. It has been found that the cleaning function of the titanium or titanium oxide cleaning layer is particularly intense in the case of boron impurities. However, the withdrawal function has also been observed for other impurities, e.g. for aluminum.

In accordance with a further possible embodiment of the invention, it is provided that the amorphous starting layer is applied by physical vapor deposition (PVD). It is likewise conceivable for the amorphous starting layer to be applied by sputtering or by plasma enhanced chemical vapor deposition (PECVD).

In accordance with one preferred embodiment of the invention, it is provided that the layer thickness of the cleaning layer is in the range of between 1 nm and 5 nm, in particular in the range of between 1 nm and 2.5 nm. In principle, thinner layer thicknesses would also be conceivable, e.g. in the range of 0.1 nm to 1 nm. Experiments have shown that an oxidation of the titanium layer can occur here under typical laboratory conditions, as a result of which the cleaning function of the titanium layer can be slightly restricted. However, even this slightly reduced cleaning function often suffices, such that even cleaning layers in the range of 0.1 nm to 1 nm may be advantageous for some applications.

In accordance with a further embodiment of the invention, it is provided that the thermal treatment takes place at a temperature in the range of between 600° C. and 800° C.

In accordance with a further embodiment of the invention, it is provided that the substrate is single-pane safety glass. Single-pane safety glass is a substrate available particularly cost-effectively, such that it is suitable, in particular, as a substrate for large-area applications such as solar cells, for example.

In accordance with a further embodiment of the invention, it is provided that the amorphous starting layer comprises at least one semiconductor material, in particular silicon and/or germanium. Silicon and/or germanium are of particular interest e.g. for solar cells or flat screens.

In accordance with a further possible embodiment of the invention, it is provided that the amorphous starting layer has a thickness of between 10 nm and 1200 nm.

In accordance with one possible embodiment of the invention, it is provided that the activator layer has a thickness which is less than that of the amorphous starting layer. Consequently, almost the entire amorphous starting layer can be converted into a closed polycrystalline end layer. In particular, it is advantageous for the ratio of the layer thicknesses to be in the range of between 1:1.1 and 1:2.0, particularly preferably approximately 1:1.7.

In accordance with one possible embodiment of the invention, it is provided that the activator layer is produced on the basis of a transition metal.

In accordance with a further embodiment of the invention, it is provided that the activator layer is deposited on the substrate and the polycrystalline end layer is formed on the substrate.

In accordance with a further embodiment of the invention, it is provided that the amorphous starting layer is deposited on the substrate and the polycrystalline end layer is formed on a metallic end layer on the substrate.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIGS. 1 to 5 are sectional views showing a simplified illustration of the work steps of a process according to an embodiment of the invention;

FIGS. 6a and 6b are graphical illustrations showing the measured charge carrier concentrations in polycrystalline silicon layers produced by a process according to embodiments of the invention;

FIG. 7 is a graphical illustration showing the charge carrier mobility in a polycrystalline silicon layer produced according to an embodiment of the invention;

FIG. 8 is a graphical illustration showing the Raman spectra of various silicon layers produced by AgILE processes;

FIG. 9 is a graphical illustration showing the leakage current between gate and source-drain of a TFT structure having a channel size of 12.5 μm×12.5 μm;

FIG. 10 is a graphical illustration showing the transistor characteristic curve of a top-gate TFT structure made from AgILE with the use of a titanium cleaning layer;

FIG. 11 are a graphical illustrations showing UI characteristic curves of a low thermal budget emitter;

FIG. 12 is a graphical illustration showing the rectifying behavior of a low thermal budget emitter structure;

FIG. 13 is a graphical illustration showing a comparison of the rectification of a commercial diode 1N4151 and a low thermal budget emitter structure produced according to the invention;

FIG. 14 is an optical micrograph of finished processed pn structures;

FIG. 15 is a graphical illustration showing the UI characteristic curve of a pn structure comprising two MILE layers with a titanium cleaning layer according to an embodiment of the invention; and

FIGS. 16 and 17 are graphical illustrations showing the dark characteristic curve and the UI characteristic curve with illumination of a low budget emitter structure having a size of 2 mm×2 mm.

### DETAILED DESCRIPTION OF THE INVENTION

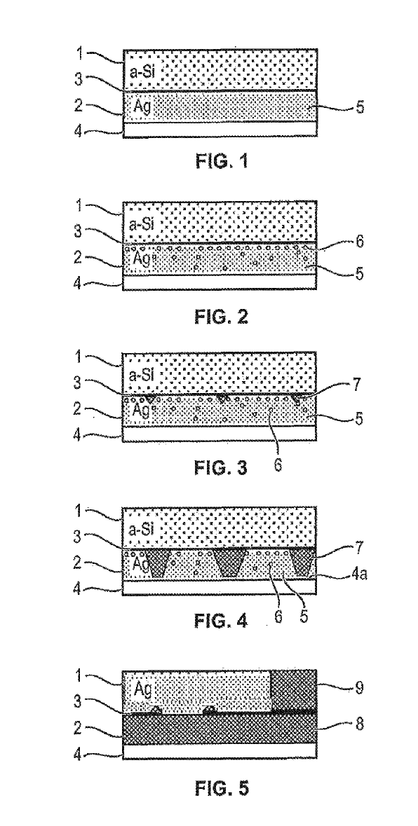

FIG. 1 shows an activator layer 2 composed of silver applied on a quartz glass substrate 4 by physical vapor deposition. The cleaning layer 3 composed of titanium and the starting layer 1 composed of amorphous silicon contaminated with impurity atoms are situated on the silver layer 2. Grain boundaries 5 lying between regions of different crystal orientations are illustrated in the silver layer.

By heat treatment below the eutectic point of the silicon-silver system, the layer exchange is initiated, as shown in FIG. 2. Silicon diffuses along the grain boundaries 5 through the titanium cleaning layer 3. In this case, impurity atoms are withdrawn from the contaminated silicon and only cleaned silicon passes into the silver layer 2. The titanium cleaning layer 3 therefore functions as a type of filter for the boron impurity atoms. Silicon accumulations 6 form within the silver layer 2.

FIG. 3 shows how a crystallization 7 of the cleaned silicon commences at the grain boundaries 5.

The vertical growth of the silicon crystallites 7 is limited by the substrate surface 4a, as illustrated in FIG. 4. A lateral growth of the crystallites 7 as far as the formation of a closed polycrystalline silicon layer (ref. no. 8 in FIG. 5) subsequently takes place. The layer thickness of the resulting silicon end layer 8 corresponds to the layer thickness of the original silver activator layer 2.

Since the layer thickness of the amorphous starting layer 1 in the exemplary embodiment shown is greater than the activator layer 2, in the end state crystallized silicon accumulations 9 also result above the closed end layer 8.

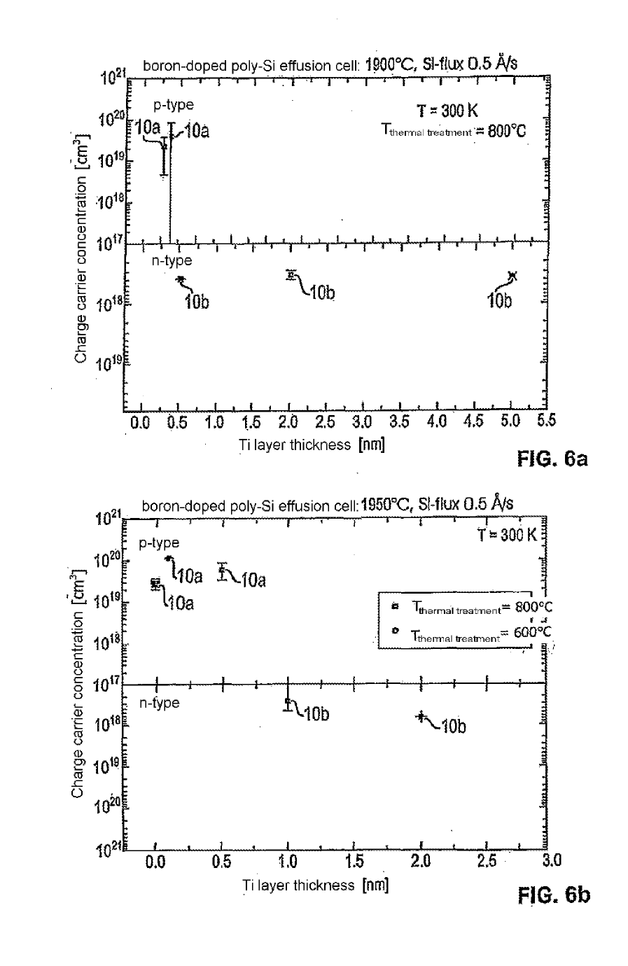

FIGS. 6a and 6b show experimentally measured charge carrier concentrations in polycrystalline silicon layers produced according to an embodiment of the process according to the invention as a function of the chosen thickness of the titanium cleaning layer. In this case, the starting layer 1 composed of amorphous silicon was doped with boron. The boron doping causes a p-type conductivity, in principle, as also measured experimentally and illustrated by the p-type measurement points 10a. As the layer thickness of the titanium cleaning layer increases, however, an n-type conductivity 10b is observed instead. The tendency that can be observed is that a larger thickness of the cleaning layer 3 in this case also leads to an increased n-type charge carrier concentration.

FIG. 6a shows the measurement results for a boron doping achieved with a boron effusion cell at a temperature of 1900° C.; an operating temperature of the effusion cell of 1950° C. was used in the case of FIG. 6b. The higher temperature leads to a higher admixture of boron impurity atoms in the silicon, such that the p-type charge carrier concentration at 1950° C. is somewhat higher, as expected. On account of the larger amount of boron impurity atoms, in this case a larger thickness of the cleaning layer is also required in order to withdraw enough boron atoms and to arrive at an n-type conductivity (on account of the background concentration of n-type impurity atoms). While an n-type conductivity can already be observed for a thickness of the cleaning layer of 0.5 nm at an effusion cell temperature of 1900° C., this was able to be observed only for a layer thickness of 1.0 nm at 1950° C. The charge carrier concentrations of approximately 3·10¹⁷ cm⁻³ measured starting from these thicknesses correspond approximately to the background concentration determined by

Secondary Ion Mass Spectroscopy. Virtually complete elimination of phosphorus impurities from the silicon was therefore able to be obtained.

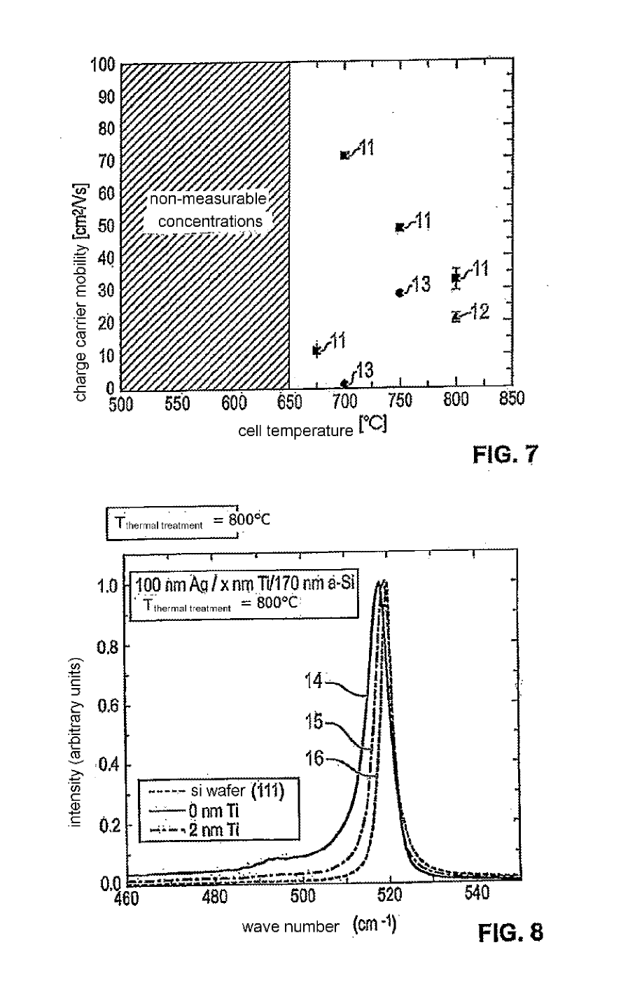

FIG. 7 shows the charge carrier mobility in a polycrystalline silicon layer produced according to an embodiment of the invention as a function of the effusion cell temperature. For all data points, the silicon was doped with phosphorus before the production of the polycrystalline layer. The data points 11 depicted as rectangular correspond to a 2 nm thick titanium cleaning layer (at a temperature of the thermal treatment of 800° C.). The triangular and round data points 12, 13 correspond to silicon layers produced without a titanium cleaning layer, respectively at thermal treatment temperatures of 600° C. and 800° C. It is evident from the measurement data that the mobility for samples without a titanium cleaning layer is on average lower than that at the same effusion cell temperature but with a titanium cleaning layer.

FIG. 8 shows the Raman spectra of various silicon layers produced by AgILE processes. A 100 nm thick activator layer composed of silver, a titanium cleaning layer and a 170 nm thick amorphous starting layer composed of silicon were used in each case. The temperature of the thermal treatment was 800° C. The intensity curves 14, 15, 16 respectively show the measurement data which were obtained: without the use of a titanium cleaning layer (intensity curve 14), with the use of a 2 nm thick titanium cleaning layer (intensity curve 15), and (for comparison) with the use of a silicon wafer (intensity curve 16). The narrower profile of the intensity curve 14 with the use of a 2 nm titanium cleaning layer indicates a better quality. This can be based on the higher purity of the silicon end layer as a result of the titanium cleaning layer.

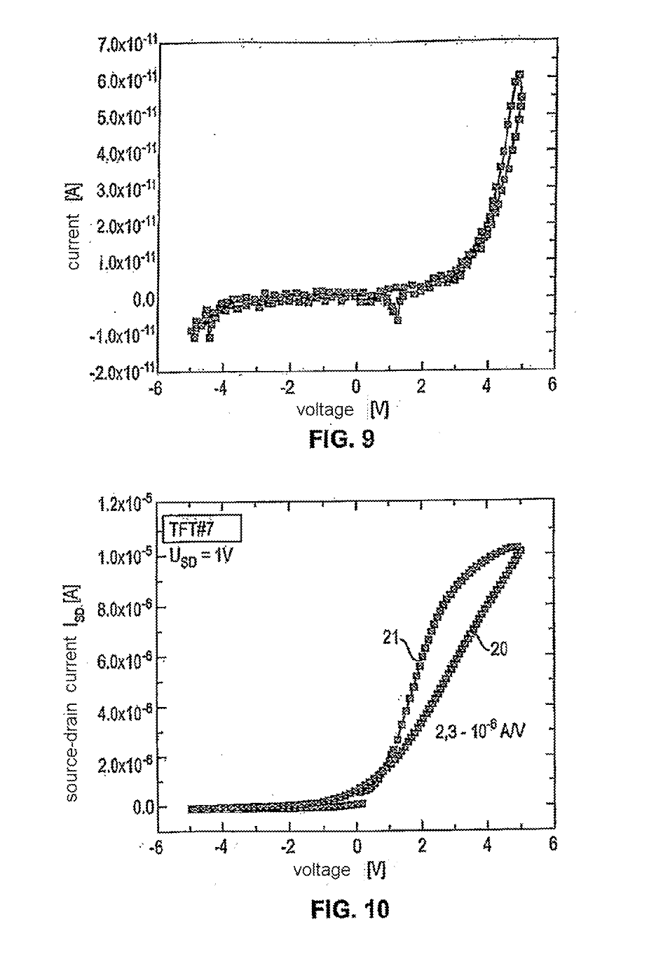

FIGS. 9 to 16 show experimental measurement results and micrographs of electronic components having a silicon layer produced according to embodiments of the invention.

A first component produced with a silicon layer according to an embodiment of the invention is a top-gate thin-film transistor (TFT). Nominally 50 nm thick phosphorus-doped silicon layers with silver activator layer and titanium cleaning layer on an SiO₂ layer were produced for the production of the top-gate TFT. The charge carrier density was approximately 1·10¹⁸ cm⁻³, determined on the basis of a non-patterned reference layer. Sputtered SiO₂ having a nominal thickness of 100 nm was used as gate oxide. An after-treatment of the oxide was dispensed with. 100 nm thick aluminum contacts were used for making contact with source, drain and gate.

FIG. 9 shows the leakage current between gate and source-drain of a TFT structure having a channel size of 12.5 μm×25 μm. It can clearly be discerned here that the leakage current in the entire measured range from −5 V to +5V is less than 10⁻¹⁰ A. This is a basic prerequisite for the use of these layers as top-gate TFTs. Besides the leakage current, the field effect mobility and the On/Off ratio were also examined.

FIG. 10 shows the transistor characteristic curve of a top-gate TFT structure made from n-type AgILE using a titanium cleaning layer (Ti.AgILE) for determining the field effect mobility.

A linear plot 20 of the transistor characteristic curve 21 is usually used for determining the field effect mobility of the charge carriers in the channel. The field effect mobility can be determined from the gradient of the linear characteristic curve

$${g}_{m} = \frac{\partial {I}_{SD}}{\partial {U}_{Gate}}$$

by way of

$$μ = \frac{{Lg}_{m}}{{WC}_{i} {U}_{SD}} .$$

In this case, L and W denote the length and width of the channel, Cᵢ denotes the capacitance of the insulator material used, and U_{SD} denotes the applied source-drain voltage. A field effect mobility of min. 112 cm²/Vs was calculated from the characteristic curve shown in FIG. 10 (parameters used: gₘ=2.3×10⁻⁶ A/V, L=25 μm, W=12.5 μm, U_{SD}=1V, Cᵢ=4.08×10⁻⁸ F/cm² (corresponds to ε=3.9)).

The measured On/Off ratio was more than three orders of magnitude. If the results described here for the top-gate TFTs are compared with bottom-gate TFTs, numerous advantages therefore emerge for top-gate TFTs:

Whereas the production of bottom-gate TFTs relies on specific substrates, the Ti.MILE layer necessary for the top-gate TFT can be applied to a wide variety of cost-effective substrates (e.g. glass). Simple realizability and adaptation to the given requirements thus result for the top-gate TFTs. With regard to transfer to a wide variety of substrates, the top-gate structure is preferable to the bottom-gate structure by a clear margin.

Bottom-gate TFTs were produced with recourse to specific gate oxides (HfO, Ta₂O₅).

These oxides were found to be unstable at the high temperatures required for the Ti.AgILE and led to short circuits between gate and source-drain. Consequently, an expedient transistor characteristic could not be achieved. Top-gate TFTs can be produced with recourse to cost-effective silicon dioxide. The oxides are not subjected to high annealing temperatures as a result of the altered process progression. Consequently, the formation of short circuits is greatly reduced and practically could not be observed in the TFTs produced previously. With regard to the usability of simple gate oxides, the top-gate structure is preferable to the bottom-gate structure by a clear margin.

Whereas practically no measurable field effect mobility was observed in the case of bottom-gate TFTs made from Ti.AgILE, a field effect mobility of more than 100 cm²/Vs was able to be measured in the case of top-gate structures. On account of the distinctly better performance, the top-gate TFT is preferable to the bottom-gate TFT.

The realizability of pn diodes comprising Ti.MILE layers was examined on the basis of the production processes low thermal budget emitter and “step by step growth.” In this case, both production processes proved to be expediently realizable. The relevant characteristic variables of these two production processes are briefly discussed below:

For the realization of the low thermal budget emitter concept, n-type Ti.MILE layers (100 nm Ag/0.1 nm Ti/oxidation: 10 min at 10⁻¹ mbar/170 nm a-Si) were grown on lightly boron-doped silicon wafers. The cell temperature of the phosphorus cell was 675° C. (P: 675° C.) during growth, which corresponds to a charge carrier concentration of approximately 2-5·10¹⁷ cm⁻³ in the finished polysilicon layers. The back contact (wafer) was realized with a 100 nm thick aluminum layer. The silver layer of the Ti.MILE was reused as front contact (Ti.MILE).

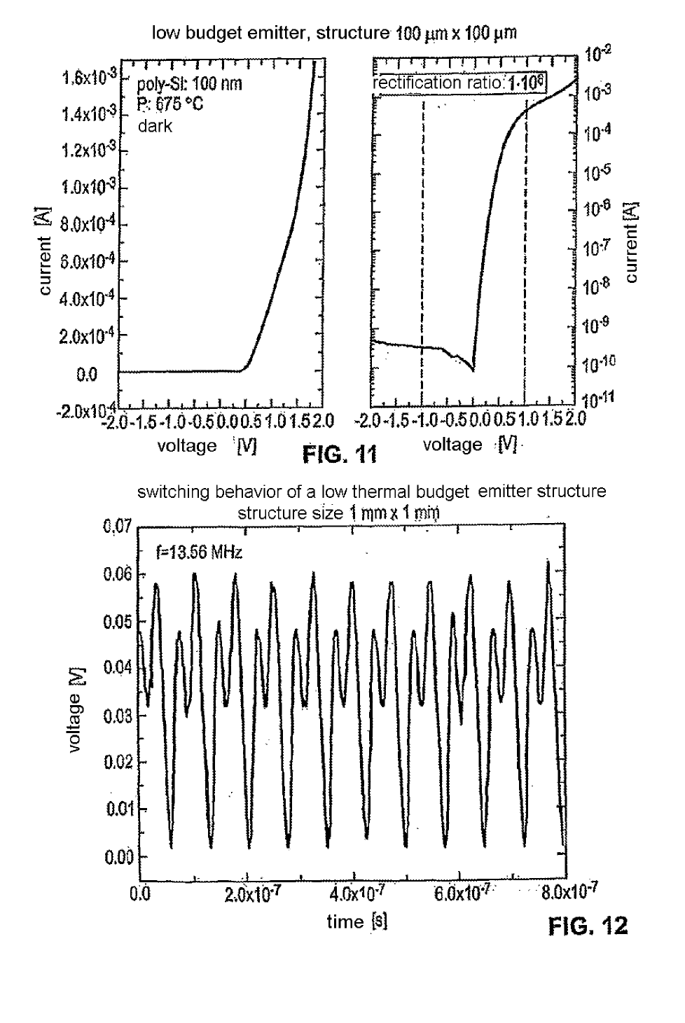

FIG. 11 shows the UI characteristic curve of this low thermal budget emitter having a structure size of 100 μm×100 μm. Comparison of the very low reverse current of approximately 10⁻¹⁰ A with the forward current (max. approximately 10⁻³ A) results in a rectification ratio of 1·10⁶ at ±1 V and 5·10⁶ at ±2 V. Furthermore, it was possible to show that diode structures having a size of 4 mm×4 mm also achieve a rectification ratio of at least approximately 2·10⁴.

In the case of the UI characteristic curve shown in FIG. 11, for a low thermal budget emitter structure having a diode size of 100 μm×100 μm, the rectification ratio at ±1 V is 1·10⁶.

FIG. 12 shows the rectification behavior of a low thermal budget emitter structure at 13.56 MHz. The applied AC voltage was 2 V.

The shift in the oscillation in the direction of positive voltages is clearly evident. The rectification could also be improved by further smoothing of this voltage. Nevertheless, the rectification is thus demounted at a frequency of 13.56 MHz. Moreover, it should be pointed out that the available construction was not optimal for the high frequencies required here. Even a slight reduction in frequency to 1.5 MHz results in a significant improvement in measurability. This is manifested in the comparison of the rectification of a commercial diode with the rectification of the low thermal budget emitter at a frequency of 1.5 MHz and an applied AC voltage of 2 V (see FIG. 5). The rectified AC voltage was smoothed via a 600 μF capacitor in all the measurements. A DC voltage of approximately 0.28 V and 0.18 V, respectively, is clearly evident. The difference between commercial diode and low thermal budget emitter is only approximately 0.1 V.

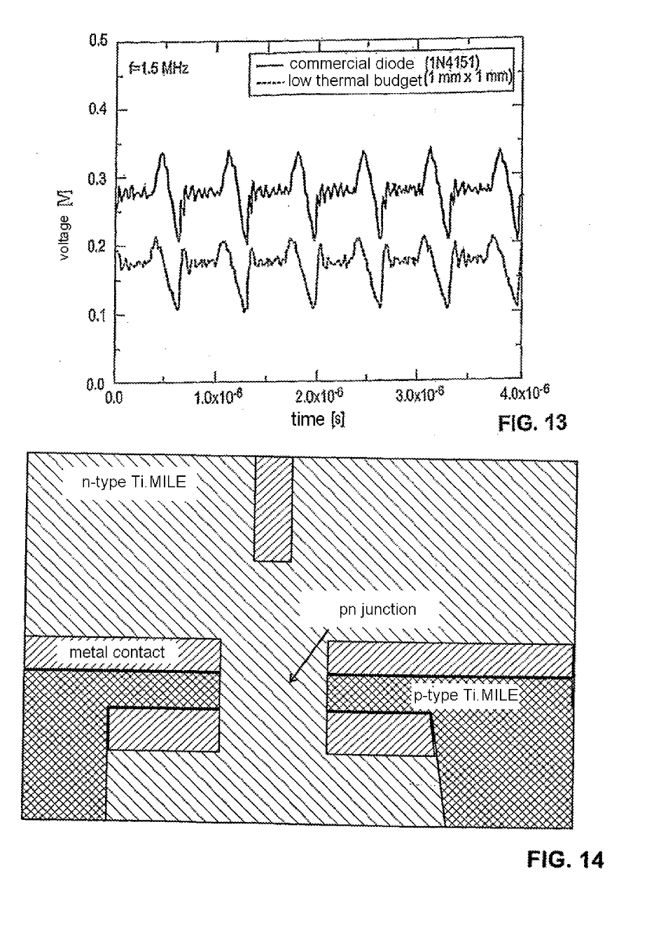

FIG. 13 shows a comparison of the rectification of a commercial diode 1N4151 and a Ti.AgILE low thermal budget emitter structure. The applied AC voltage was 2 V.

“Step by step” Growth

For “step by step” growth, first n-type Ti.MILE structures (200 nm Ag/2 nm Ti/oxidation: 10 min at 10⁻¹ mbar/340 nm a-Si, P: 675° C.) were grown on HOQ310 quartz glass, and the silver was removed wet-chemically after a heat treatment step at 800° C. Afterward, the p-type Ti.MILE structure (200 nm Ag/0 nm Ti/oxidation: 10 min at 10⁻¹ mbar/340 nm a-Si, B: 1950° C.) was applied, and the silicon layer was crystallized at 600° C. The charge carrier concentration of the Ti.MILE layers is approximately 5-8·10¹⁷ cm⁻³. For the characterization of the pn structures, the silver layer was removed wet-chemically and replaced by contacts composed of 100 nm aluminum. The size of the pn structures was 100 μm×100 μm. FIG. 14 shows an optical micrograph of the finished processed pn structures.

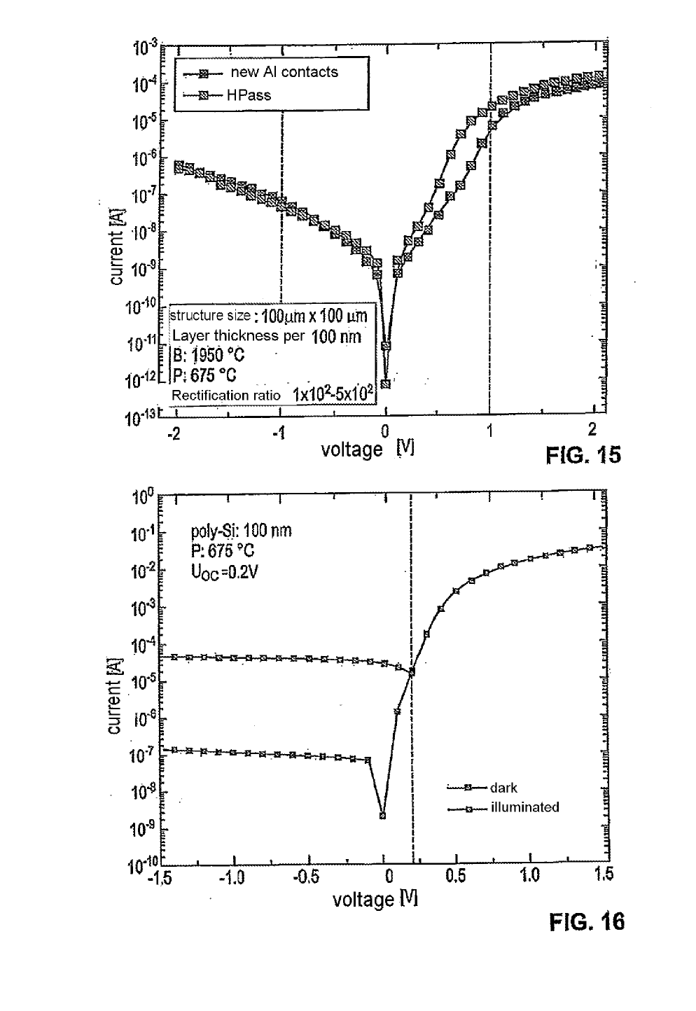

FIG. 15 shows the UI characteristic curve of a pn structure comprising two Ti.MILE layers having a structure size of 100 μm×100 μm. Comparison of the relatively low reverse current of approximately 10⁻⁷ A with the forward current (max. approximately 10⁻⁵ A) yields a rectification ratio of approximately 1·10² at ±1 V (black curve). As a result of a step of passivation of the acceptors in the p-type layer of the pn structures with hydrogen, it was possible to achieve an improvement in the rectification ratio to approximately 5·10².

A further important field of application for the polycrystalline silicon layers produced according to the invention is thin-film solar cells.

The realizability of Ti.MILE solar cell structures was examined on the basis of the production process low thermal budget emitter. The results are described below.

For the realization of the low thermal budget emitter concept, n-type Ti.MILE layers (100 nm Ag/0.1 nm Ti/oxidation: 10 min at 10⁻¹ mbar/170 nm a-Si) were grown on lightly boron-doped silicon wafers. The cell temperature of the phosphorus cell was 675° C. (P: 675° C.) during growth, which corresponds to a charge carrier concentration of approximately 2-5·10¹⁷ cm⁻³ in the finished polysilicon layers. The back contact (wafer) was realized with a 100 nm thick aluminum layer. The silver layer of the Ti.MILE was reused as front contact (Ti.MILE).

FIG. 16 shows the dark characteristic curve (black curve) and the UI characteristic curve with illumination of a Ti.MILE low thermal budget emitter structure having a size of 2 mm×2 mm. On account of the silver layer that had not yet been removed, the structures were illuminated through the hillocks of the Ti.MILE layer with the aid of a halogen lamp. The structure shown here yielded a terminal voltage of 0.2 V and a significant increase in current with illumination.

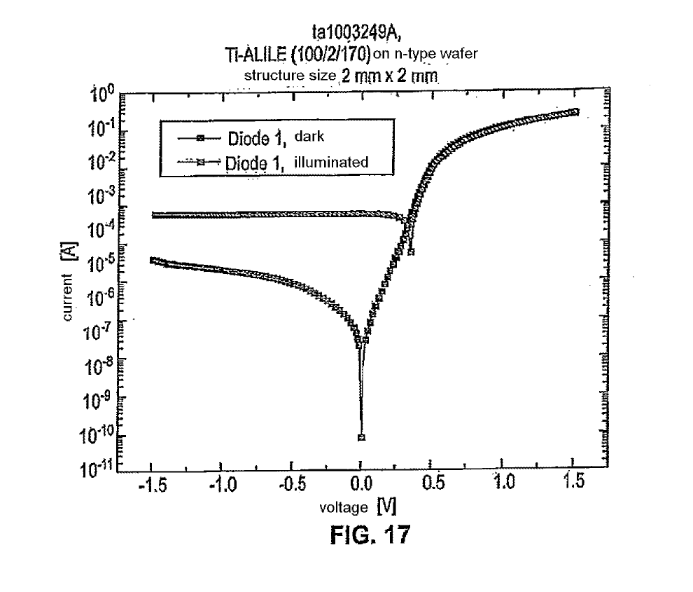

On account of the similar characteristic of the characteristic curves, the application potential of the Ti.AgILE low thermal budget emitter is assessed as very good (see FIGS. 16 and 17). It should be taken into consideration here that the Ti.ALILE emitters were already measured with finger-like front contacts and thus exhibit a better characteristic. On account of the not yet optimal front contacts (silver layer of the Ti.MILE), the characteristic of the Ti.AgILE structure might even exceed the characteristic data of the Ti.ALILE emitters.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-13. (canceled)

14. A process for producing a polycrystalline layer, the process comprising the steps of:
applying to a substrate a layer sequence comprising at least:
an amorphous starting layer provided with impurities,
a metallic activator layer, and
a cleaning layer based on titanium or titanium oxide arranged between the starting
layer and the activator layer and serving for withdrawing the impurities from the starting layer; and
carrying out a thermal treatment after applying the layer sequence to form a polycrystalline end layer.

15. The process as claimed in claim 14, wherein the impurities are boron impurities.

16. The process as claimed in claim 14, wherein the amorphous starting layer is applied by physical vapor deposition (PVD).

17. The process as claimed in claim 14, wherein the cleaning layer has a layer thickness in a range of between 2 nm and 10 nm.

18. The process as claimed in claim 17, wherein the cleaning layer has a layer thickness in a range of between 2 nm and 4 nm.

19. The process as claimed claim 14, wherein the thermal treatment takes place at a temperature in a range of between 600° C. and 800° C.

20. The process as claimed in claim 14, wherein the substrate is single-pane safety glass.

21. The process as claimed in claim 14, wherein the amorphous starting layer comprises at least one semiconductor material.

22. The process as claimed in claim 21, wherein the at least one semiconductor material comprises at least one of silicon and germanium.

23. The process as claimed in claim 14, wherein the amorphous starting layer has a thickness of between 10 nm and 1200 nm.

24. The process as claimed in claim 14, wherein the activator layer has a thickness less than that of the amorphous starting layer.

25. The process as claimed in claim 24, wherein a ratio of the thickness of the activator layer to the thickness of the amorphous starting layer is in a range of between 1:1.1 and 1:2.0.

26. The process as claimed in claim 14, wherein the activator layer is produced based on a transition metal.

27. The process as claimed in claim 14, wherein the activator layer is deposited on the substrate and the polycrystalline end layer is formed on the substrate.

28. The process as claimed in claim 14, wherein the amorphous starting layer is deposited on the substrate and the polycrystalline end layer is formed on a metallic end layer on the substrate.

29. A process for setting doping in polycrystalline silicon, the process comprising steps of:
applying to a substrate a layer sequence comprising at least:
an amorphous starting layer provided with impurities,
a metallic activator layer, and
a cleaning layer based on titanium or titanium oxide arranged between the starting layer and the activator layer; and
carrying out a thermal treatment after applying the layer sequence to form a polycrystalline end layer;
wherein the doping is set by a suitable choice of thickness of the cleaning layer.
